(19) United States
(12) Patent Application Publication
(10) Pub. No.: US 2025/0072184 A1
(43) Pub. Date: Feb. 27, 2025

(54) EPITAXIAL WAFER STRUCTURE AND FUNCTIONAL DEVICE, AND MANUFACTURING METHODS THEREOF

(71) Applicant: Wuhan Tuopu Jingyan Semiconductor Technology Co. Ltd., Wuhan, Hubei (CN)

(72) Inventors: Ying QIN, Wuhan (CN); Yifei ZHANG, Wuhan (CN); Lina CHEN, Wuhan (CN)

(21) Appl. No.: 18/544,028

(22) Filed: Dec. 18, 2023

(30) Foreign Application Priority Data
Aug. 24, 2023 (CN) 202311077989.1

(51) Int. Cl. H01L 33/62; H01L 25/075; H01L 33/00

(52) U.S. Cl. CPC H01L 33/62; H01L 25/0753; H01L 33/0093

(57) ABSTRACT

An epitaxial wafer structure, an epitaxial function device, and manufacturing methods thereof are provided in the present disclosure. The epitaxial wafer structure is configured to be bonded to a driver substrate provided with a plurality of driver units including a plurality of non-defective driver units and a plurality of defective driver units. The epitaxial wafer structure includes a carrier substrate, a plurality of functional units disposed on the carrier substrate, and a plurality of placeholder units disposed on the carrier substrate. Each of the plurality of functional units on the carrier substrate is corresponding in position to one of the plurality of non-defective driver units on the driver substrate. Each of the plurality of placeholder units on the carrier substrate is corresponding in position to one of the plurality of defective driver units on the driver substrate.

### CROSS-REFERENCE TO RELATED APPLICATIONS

This application claims priority to Chinese Patent Application No. 2023110779891, filed on Aug. 24, 2023, the content of which is hereby incorporated by reference in its entirety.

### TECHNICAL FIELD

The present disclosure relates to the technical field of semiconductor device, and particularly to an epitaxial wafer structure and a functional device and manufacturing methods thereof.

### BACKGROUND

In the current manufacture process of semiconductor-related devices, it is generally required to epitaxially form a specific functional structure on a substrate such as a wafer, and then bond the substrate to another substrate provided with a drive circuit, to combine the functional structure and the drive circuit into a device as a whole. This process has been widely applied in the manufacture of the micro light emitting diode (Micro LED).

In the practical production, the drive circuit is generally an integrated circuit prepared on a first wafer, and the first wafer is generally formed with a plurality of dies each of which contains the drive circuit. The dies are formed with a certain yield due to the limitation of the technology, so that the first wafer always contains defective die(s). On the other hand, the epitaxially formed functional structures also have a certain yield, so that a second wafer formed with a plurality of functional structures always contains defective functional structure(s). These two factors together lead to the low yield of the devices obtained by bonding the first wafer and the second wafer and thus the waste of resources.

### SUMMARY

In view of the above, an epitaxial wafer structure and a functional device and manufacturing methods thereof are provided to increase the resource utilization efficiency and improve the yield of bonded devices.

An epitaxial wafer structure is provided. The epitaxial wafer structure is configured to be bonded to a driver substrate provided with a plurality of driver units including a plurality of non-defective driver units and a plurality of defective driver units. The epitaxial wafer structure includes a carrier substrate, a plurality of functional units disposed on the carrier substrate, and a plurality of placeholder units disposed on the carrier substrate. Each of the plurality of functional units on the carrier substrate is corresponding in position to one of the plurality of non-defective driver units on the driver substrate. Each of the plurality of placeholder units on the carrier substrate is corresponding in position to one of the plurality of defective driver units on the driver substrate.

In some embodiments, each of the plurality of functional units includes a micro light emitting diode.

In some embodiments, surfaces of the placeholder units away from the carrier substrate are flush with surfaces of the functional units away from the carrier substrate.

In some embodiments, the epitaxial wafer structure further includes a plurality of first bonding layers disposed between the plurality of functional units and the carrier substrate, respectively. The plurality of functional units are bonded to the carrier substrate via the plurality of first bonding layers.

In some embodiments, the epitaxial wafer structure further includes a third bonding layer covering the carrier substrate and disposed between the plurality of first bonding layers and the carrier substrate. The plurality of function bonding layers are bonded to the third bonding layer.

In some embodiments, a material of the plurality of first bonding layers is selected from a group consisting of silicon oxide, silicon nitride, epoxy resin, polyimide, indium tin oxide, metal, and any combination thereof.

In some embodiments, a material of the third bonding layer is selected from a group consisting of silicon oxide, silicon nitride, epoxy resin, polyimide, indium tin oxide, metal, and any combination thereof.

In some embodiments, the plurality of placeholder units are made of a semiconductor material. The epitaxial wafer structure further includes a plurality of second bonding layers disposed between the plurality of placeholder units and the carrier substrate, respectively. The plurality of placeholder units are bonded to the carrier substrate via the plurality of second bonding layers.

In some embodiments, the epitaxial wafer structure further includes a dielectric layer disposed in a space between any adjacent two of the plurality of functional units, between any adjacent two of the plurality of placeholder units, or between one of the plurality of functional units and one of the plurality of placeholder units adjacent to each other.

In some embodiments, the plurality of placeholder units are made of a dielectric material same as that of the dielectric layer.

A method for manufacturing the epitaxial wafer structure is provided, including:
forming an epitaxial functional layer on a first native substrate;
cutting the epitaxial functional layer and the first native substrate into a plurality of functional units and a plurality of first native sub-substrates, wherein the plurality of functional units are respectively located on the plurality of first native sub-substrates;
providing the carrier substrate, and bonding the plurality of functional units with the plurality of first native sub-substrates attached thereto to the carrier substrate so that the plurality of functional units are positioned between the plurality of first native sub-substrates and the carrier substrate;
disposing a plurality of placeholder units on the carrier substrate; and
removing the plurality of first native sub-substrates to expose the plurality of functional units.

In some embodiments, the method for manufacturing the epitaxial wafer structure further includes: prior to the cutting the epitaxial functional layer and the first native substrate, forming a first bonding material layer on a side of the epitaxial functional layer away from the first native substrate; and cutting the first bonding material layer into a plurality of first bonding layers while cutting the epitaxial functional layer and the first native substrate, wherein the plurality of first bonding layers are respectively located on the plurality of functional units at a side away from the plurality of first native sub-substrates.

In some embodiments, the disposing the plurality of placeholder units on the carrier substrate comprises:
epitaxially forming an epitaxial placeholder layer with a semiconductor material on a second native substrate;
forming a second bonding material layer on a side of the epitaxial placeholder layer away from the second native substrate;
cutting the second bonding material layer, the epitaxial placeholder layer, and the second native substrate into a plurality of second bonding layers, a plurality of placeholder units, and a plurality of second native sub-substrates, respectively, wherein the plurality of placeholder units are respectively located on the plurality of second native sub-substrates, and the plurality of second bonding layers are respectively located on the plurality of placeholder units; and
bonding the plurality of placeholder units with the plurality of second native sub-substrates attached thereto to the carrier substrate via the plurality of second bonding layers so that the plurality of placeholder units are positioned between the plurality of second native sub-substrates and the carrier substrate.

In some embodiments, the method for manufacturing the epitaxial wafer structure further includes: forming a dielectric layer between any two adjacent of the plurality of functional units by using a dielectric material. The disposing the plurality of placeholder units on the carrier substrate comprises: forming the plurality of placeholder units with the dielectric material while forming the dielectric layer.

A functional device is provided, including: a driver substrate; a plurality of driver units disposed on the driver substrate and including a plurality of non-defective driver units and at least one defective driver units; a plurality of functional units located opposite to and electrically connected to the plurality of non-defective driver units, respectively; and a plurality of placeholder units located opposite to the plurality of defective driver units, respectively.

In some embodiments, the functional device further includes a plurality of sixth bonding layers disposed between the plurality of functional units and the plurality of non-defective driver units, respectively. The plurality of functional units are bonded to the plurality of non-defective driver units via the plurality of sixth bonding layers, respectively.

In some embodiments, a material of the plurality of sixth bonding layers includes metal.

In some embodiments, the functional device further includes a plurality of electrode layers disposed between the plurality of functional units and the plurality of non-defective driver units, respectively.

A method for manufacturing the functional device is further provided, including:
providing the driver substrate provided with the plurality of driver units, and acquiring positions of the plurality of non-defective driver units and the plurality of defective driver units;
providing an epitaxial wafer structure comprising a carrier substrate and the plurality of functional units and the plurality of placeholder units disposed on the carrier substrate, wherein each of the plurality of functional units on the carrier substrate is corresponding in position to one of the plurality of non-defective driver units on the driver substrate; and each of the plurality of placeholder units on the carrier substrate is corresponding in position to one of the plurality of defective driver units on the driver substrate;
bonding the epitaxial wafer structure to the driver substrate such that the plurality of functional units located opposite to the plurality of non-defective driver units, respectively, and the plurality of placeholder units located opposite to the plurality of defective driver units, respectively; and
removing the carrier substrate.

In some embodiment, the driver substrate is further provided with a fourth bonding layer located on the plurality of driver units. The providing the epitaxial wafer structure includes: forming a fifth bonding layer on the plurality of the functional units. The bonding the epitaxial wafer structure to the driver substrate includes: bonding the fourth bonding layer to the fifth bonding layer to bond the plurality of driver units to the plurality of the functional units.

In some embodiment, the method for manufacturing the functional device further includes: prior to the bonding the epitaxial wafer structure to the driver substrate, forming an electrode layer on the plurality of the functional units.

Generally, a plurality of functional structures are epitaxially formed on a first substrate and then bonded to a plurality of driver units provided on a second substrate. In the conventional technology, the positions of the functional structures cannot be adjusted. Consequently, in the bonding process, some of the non-defective functional structures on the first substrate may be mispaired with the defective driver units on the second substrate, which not only leads to the low yield of the devices obtained after the bonding, but also causes the waste of resources.

In the epitaxial wafer structure of the present disclosure, the carrier substrate, the functional unit, and the placeholder unit are included. The position of the functional unit on the carrier substrate corresponds to the position of the non-defective driver unit on the driver substrate, and the position of the placeholder unit on the carrier substrate corresponds to the position of the driver unit on the driver substrate. By providing the placeholder unit, the epitaxial wafer structure can be bonded to the driver substrate to allow the electrical connection between the non-defective driver unit and the functional unit, thereby avoiding the mispairing problem which is unavoidable in the conventional technology. In addition, the functional unit and the effective drive circuit can be saved, and the yield of the resulting devices can also be improved.

It should be understood that corresponding to the above epitaxial wafer structure, the manufacturing method provided in the present disclosure involves forming an epitaxial functional layer on a native substrate, cutting the epitaxial functional layer and the native substrate into a plurality of functional units and a plurality of native sub-substrates, and then transferring the functional units onto a carrier substrate. In the present disclosure, the functional units can be re-arranged and the positions thereof can be adjusted according to needs on the carrier substrate.

The above illustration is only a summary of the technical solution of the present disclosure. In order to better understand the technical means of the present disclosure and implement them in accordance with the contents of the descriptions, the preferred embodiment of the present disclosure with the drawings are described in detail as follows.

### BRIEF DESCRIPTION OF THE DRAWINGS

In order to illustrate the embodiments of the present disclosure more clearly, the drawings used in the embodiments will be described briefly. Apparently, the following described drawings are merely for some embodiments of the present disclosure, and the drawings of other embodiments can be derived by those of ordinary skill in the art without any creative effort.

FIG. 1 shows a schematic structural top view of an epitaxial wafer structure.

FIG. 2 shows a schematic structural view of a driver substrate provided a plurality of driver units.

FIG. 3 shows a schematic structural cross-sectional view taken along A-A′ of FIG. 1.

FIG. 4 shows a flow chart of a method for manufacturing the epitaxial wafer structure.

FIG. 5 shows a schematic structural view of forming an epitaxial functional layer on a first native substrate.

FIG. 6 shows a schematic structural view of providing a first fixing member on basis of the structure shown in FIG. 5.

FIG. 7 shows a schematic view of a structure obtained by cutting the epitaxial functional layer and the first native substrate on basis of the structure shown in FIG. 6.

FIG. 8 shows a schematic structural view of forming an epitaxial placeholder layer and a second bonding material layer on a second native substrate.

FIG. 9 shows a schematic view of a structure obtained by cutting on basis of the structure show in FIG. 8.

FIG. 10 shows a schematic structural view of a structure obtained by transferring placeholder units and functional units onto a carrier substrate.

FIG. 11 shows a schematic view of a structure obtained by removing first native sub-substrates and second native sub-substrates from the structure of FIG. 10.

FIG. 12 shows a schematic view of a structure obtained by transferring functional units onto a carrier substrate with placeholder units and a dielectric layer having not been provided.

FIG. 13 shows a schematic view of forming the placeholder units and the dielectric layer on basis of the structure shown in FIG. 12.

FIG. 14 shows a flow chart of a method for manufacturing a functional device.

FIG. 15 shows a schematic structural cross-sectional view taken along B-B′ of FIG. 2.

FIG. 16 shows a structural schematic view of forming an electrode layer and a fourth bonding layer on basis of the structure shown in FIG. 3.

FIG. 17 shows a schematic view of a structure obtained by bonding the epitaxial wafer structure of FIG. 16 to the driver substrate of FIG. 15.

FIG. 18 shows a schematic view of a structure obtained by removing the carrier substrate from the structure shown FIG. 17.

The reference signs and their meanings are as follows.

10, carrier substrate; 11, functional unit; 12, placeholder unit; 20, driver substrate; 21, non-defective driver unit; 22, defective driver unit; 110, third bonding layer; 120, dielectric layer; 130, electrode layer; 210, fourth bonding layer; 220, fifth bonding layer; 30, first native substrate; 31, first native sub-substrate; 310, epitaxial functional layer; 320, first bonding material layer; 321, first bonding layer; 330, first fixing member; 40, second native substrate; 41, second native sub-substrate; 410, epitaxial placeholder layer; 420, second bonding material layer; 421, second bonding layer; and 430, second fixing member.

### DETAILED DESCRIPTION

The present disclosure will now be described in detail with reference to the drawings in order to facilitate understanding of the present disclosure. The drawings show some preferred embodiments of the present application. However, the present disclosure may be implemented in many different forms and is not limited to the embodiments described herein. In contrast, the specific embodiments provided herein are only for understanding the disclosure of the present application more thoroughly and comprehensively.

Unless otherwise defined, all technical and scientific terms used herein have the same meaning as those normally understood by those of ordinary skill in the art. The terms used herein in the descriptions of the present disclosure are for the purpose of describing specific embodiments only and are not intended to limit the present disclosure. The term “and/or” as used herein includes any and all combinations of one or more relevant listed items.

It shall be understood that, an element or a layer, when being referred to as being “above”, “adjacent to”, “connected to”, or “coupled with” another element or layer, may be directly above, adjacent to, connected to, or coupled with the other element or layer, or intervening element(s) or layer(s) may be present. In contrast, when an element or a layer is referred to as being “directly above”, “directly adjacent to”, “directly connected to”, or “directly coupled with” another element or layer, there is no an intermediate element or a layer. It shall note that although the terms “first”, “second”, “third”, etc. may be used to describe various elements, components, zones, layers, and/or portions, these elements, components, zones, layers, and/or portions should not be limited by these terms. These terms are only for distinguishing one element, component, zone, layer, or portion from the other elements, components, zones, layers, or portions. Therefore, without departing from the teaching of the present disclosure, the first element, component, zone, layer, or portion discussed below can be indicated as the second element, component, zone, layer, or portion.

Spatial relation terms such as “below”, “under”, “lower”, “neath”, “above”, “over”, etc., may be used herein for ease of description to describe the relation of a component or feature shown in the drawing to the other components or features. It shall be understood that, in addition to the orientations shown in the drawings, the spatial relation terms are intended to include different orientations of the devices in use and operation. For example, if the device in the drawings is inverted, then the elements or features described as “below”, “under”, or “neath” the other elements or features will be oriented as “above” the other elements or features. Therefore, the exemplary terms “below” and “under” can include both upside and downside orientations. The device may additionally be oriented (rotated for 90 degrees or other orientations) and the spatial terms used herein will be interpreted accordingly.

The terms used herein is for the purpose of describing specific embodiments only and is not intended to limit the present disclosure. As used herein, the singular forms “a”, “an” and “the”, are also intended to include the plural forms unless otherwise clearly dictated. It shall be understood that the terms “comprise” and/or “include”, when used in the descriptions, determines the presence of features, integers, steps, operations, elements, and/or components, but does not exclude the presence or addition of one or more other features, integers, steps, operations, elements, components, and/or groups. As used herein, the term “and/or” includes any and all combinations of related listed items.

The embodiments of the present disclosure are described herein with reference to a cross-sectional view which is a schematic illustration of a preferred embodiment (and an intermediate structure) of the present disclosure. Thus, variations from the illustrated shape due to, for example, manufacturing techniques and/or tolerances may be expected. Therefore, the embodiments of the present disclosure should not be limited by the particular shape of the regions shown herein, but rather include shape deviations due to, for example, fabrication. The regions shown in the drawings are substantially schematic, and their shapes are not intended to show the actual shape of the regions of the device and limit the scope of the present disclosure.

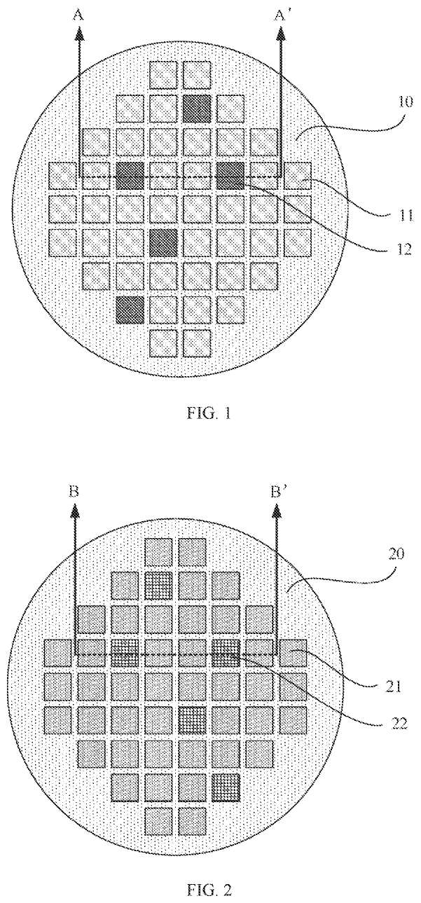

The present disclosure provides an epitaxial wafer structure. FIG. 1 shows a schematic top view of the epitaxial wafer structure.

Referring to FIG. 1, the epitaxial wafer structure includes a carrier substrate 10, a plurality of functional units 11, and a plurality of placeholder units 12. The plurality of functional units 11 and the plurality of placeholder units 12 are disposed on the carrier substrate 10. The plurality of functional units 11 can be bonded to the carrier substrate 10. The functional units 11 are spaced from each other. The placeholder units 12 are spaced from each other. The functional unit 11 is spaced from the placeholder unit 12. The epitaxial wafer structure is configured to be bonded to a driver substrate 20 provided with a plurality of driver units. FIG. 2 shows a schematic structural view of the driver substrate 20 provided with the driver units. Referring to FIG. 2, the plurality of driver units provided on the driver substrate 20 are spaced from each other and includes a plurality of non-defective driver units 21 and at least one defective driver unit 22. Referring to FIG. 1 in combination with FIG. 2, each of the plurality of functional units 11 on the carrier substrate 10 is corresponding in position to one of the plurality of non-defective driver units 21 on the driver substrate 20. Each of the plurality of placeholder units 12 on the carrier substrate 10 is corresponding in position to one of the plurality of defective driver units 22 on the driver substrate 20. Herein, “each of the plurality of functional units 11 on the carrier substrate 10 being corresponding in position to one of the plurality of non-defective driver units 21 on the driver substrate 20” refers to that when the carrier substrate 10 is entirely bonded to the driver substrate 20, each of the plurality of functional units 11 is opposite to and bonded to the corresponding one of the plurality of non-defective driver units 21. Likewise, “each of the plurality of placeholder units 12 on the carrier substrate 10 being corresponding in position to one of the plurality of defective driver units 22 on the driver substrate 20” refers to that when the carrier substrate 10 is entirely bonded to the driver substrate 20, each of the plurality of placeholder units 12 is opposite to and bonded to the corresponding one of at least one defective driver unit 22.

The functional unit 11 is configured to perform a specific function. The driver unit is configured to drive the functional unit 11 to perform the specific function. The placeholder unit 12 is configured to occupy a specific region on the carrier substrate 10 so that the carrier substrate 10 can be normally bonded to the driver substrate 20. The placeholder unit 12 can be a defective functional unit 11. Alternatively, the placeholder unit 12 can be a unit without any specific function. The non-defective driver unit 21 refers to which driver unit capable of performing the specific function normally. The defective driver unit 22 refers to which driver unit incapable of performing the specific function normally. In some exemplary embodiments, the functional unit 11 can be a single-layer structure or a laminated structure formed with a plurality of materials. For example, the functional unit 11 can include a micro light emitting diode (Micro LED). Further, the functional unit 11 can include a p-type semiconductor layer and an n-type semiconductor layer in stacked arrangement.

In some exemplary embodiments, the functional unit 11 can be a die containing a micro light emitting diode and located on the carrier substrate 10. The driver unit can be a die containing an integrated circuit and located on the driver substrate 20. The functional unit 11 can be electrically connected to the driver unit to form a chip with the specific function, such as a micro light emitting diode chip.

In some exemplary embodiments, the functional unit 11 can contain a semiconductor material. The functional unit 11 can contain, for example, one or more of gallium nitride (GaN), gallium arsenide (GaAs), indium gallium nitride (InGaN), or aluminum indium gallium phosphide (AlInGaP).

In some exemplary embodiments, the functional unit 11 can be a patterned functional unit. That is, the functional unit 11 can be divided into a plurality of devices that can be used independently. In other embodiments, the functional unit 11 can be a non-patterned functional unit. That is, the functional unit 11 can include no material layer having a specific patterned structure.

Referring to FIGS. 1 and 2, in some exemplary embodiments, the total number of the functional units 11 and the placeholder unit(s) 12 can be equal to the total number of the driver units, so that the normal bonding between the driver substrate 20 and the carrier substrate 10 can be ensured. Further, the driver substrate 20 and the carrier substrate 10 can have the same size, so that they can be bonded in the same process procedure, thereby improving the success rate of the manufacture thereof.

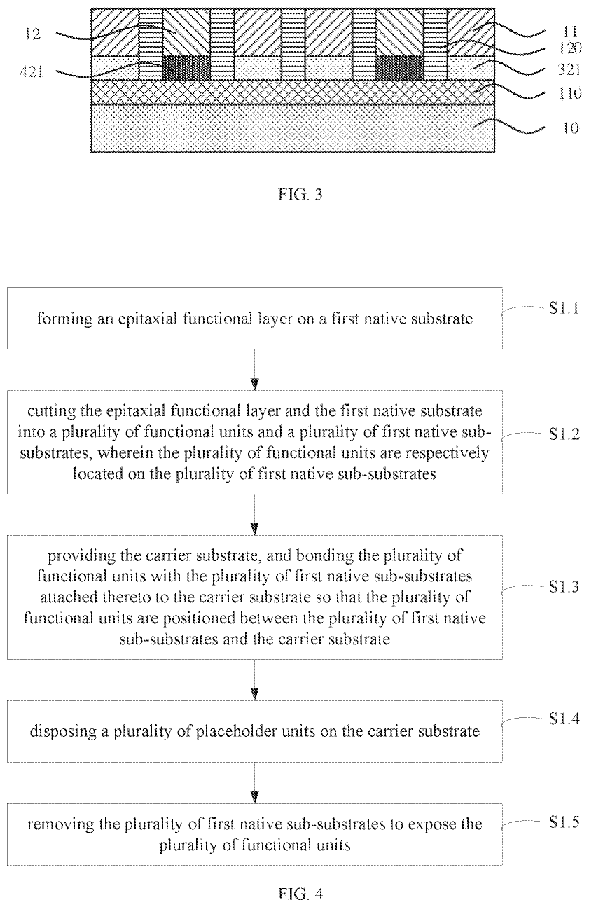

FIG. 3 shows a schematic structural cross-sectional view taken along A-A′ of FIG. 1. Referring to FIG. 3, a surface of the placeholder unit 12 away from the carrier substrate 10 is flush with a surface of the functional unit 11 away from the carrier substrate 10. The flush arrangement of the surfaces of the placeholder units 12 and the functional unit(s) 11 can ensure the flatness of a functional layer subsequently formed on the functional units 11 and thus ensure effective bonding between the functional units 11 and the non-defective driver units 21, thereby improving the yield of resulting devices.

Referring to FIG. 3, in some exemplary embodiments, the epitaxial wafer structure can further include a first bonding layer 321 disposed between the functional unit 11 and the carrier substrate 10. The functional unit 11 can be bonded to the carrier substrate 10 via the first bonding layer 321. The first bonding layer 321 can be used to improve bonding stability between the functional unit 11 and the carrier substrate 10 and protect the functional unit 11.

In some exemplary embodiments, the first bonding layer 321 can be made of a material including an inorganic material and/or an organic material. The inorganic material can include one or more of oxide, nitride, or metal. The organic material can include a photoresist material.

In some exemplary embodiments, the material of the first bonding layer 321 can include one or more of silicon oxide, silicon nitride, epoxy resin, polyimide, indium tin oxide, or metal. In some exemplary embodiments, the material of the first bonding layer 321 can be an inorganic oxide material or an inorganic nitride material.

In some exemplary embodiments, the epitaxial wafer structure can further include a third bonding layer 110. The third bonding layer 110 can cover the carrier substrate 10 and be disposed between the functional unit 11 and the carrier substrate 10. The first bonding layer 321 can be bonded to the third bonding layer 110 to further improve the bonding strength between the functional unit 11 and the carrier substrate 10, avoiding the dislocation or detachment of the functional unit 11 from the carrier substrate 10 in the subsequent process of bonding the carrier substrate 10 to the driver substrate 20.

In some exemplary embodiments, the third bonding layer 110 can be made of a material including an inorganic material and/or an organic material. The inorganic material can include one or more of oxide, nitride, or metal. The organic material can include a photoresist material.

In some exemplary embodiments, the material of the third bonding layer 110 can include one or more of silicon oxide, silicon nitride, epoxy resin, polyimide, indium tin oxide, or metal. In some exemplary embodiments, the material of the third bonding layer 110 can be an inorganic oxide material or an inorganic nitride material. In some exemplary embodiments, the material of the third bonding layer 110 can be the same as or different from that of the first bonding layer 321.

The material of the third bonding layer 110 can be a material formed on the carrier substrate 10 by deposition or a material obtained by the reaction of the carrier substrate 10. For example, the material of the third bonding layer 110 can be an oxide material obtained by the oxidization of the carrier substrate 10.

In some exemplary embodiments, the first bonding layer 321 can be bonded to the third bonding layer 110 by the method of metal bonding, oxide bonding, or mixed bonding. It should be understood that the specific bonding method depends on the materials of the first bonding layer 321 and the third bonding layer 110.

Referring to FIG. 3, in some exemplary embodiments, the epitaxial wafer structure can further include a dielectric layer 120 disposed between the functional units 11 or the placeholder units 12. The dielectric layer 120 can be disposed in a space between the functional unit 11 and the placeholder unit 12 adjacent to each other, a space between any two adjacent functional units 11, or a space between any two adjacent placeholder units 12.

In some exemplary embodiments, the surface of the functional unit 11 away from the carrier substrate 10 can be exposed from the dielectric layer 120, so that the functional unit 11 can be electrically connected to the non-defective driver unit 21 in the subsequent process. Further, a surface of the dielectric layer 120 away from the carrier substrate 10 can be flush with the surface of the functional unit 11 away from the carrier substrate 10.

In some exemplary embodiments, the dielectric layer 120 can contain a dielectric material. Further, the placeholder unit 12 can also include the dielectric material, so that the placeholder unit 12 and the dielectric layer 120 can be formed in the same process, thereby simplifying the manufacture process. For example, the material of the dielectric layer 120 can include an inorganic oxide material, an inorganic nitride material, a metal material, or an insulating material, and the placeholder unit 12 can correspondingly include the inorganic oxide material, the inorganic nitride material, the metal material, or the insulating material. In some embodiments, the dielectric layer 120 can include a photoresist material, and the placeholder unit 12 can also include the photoresist material.

In some other exemplary embodiments, the placeholder unit 12 can include a semiconductor material. By using the semiconductor material in the placeholder unit 12, the placeholder unit 12 can have mechanical and bonding performances similar to those of the functional unit 11, thereby improving the consistency of the functional unit 11 with the placeholder unit 12 on the carrier substrate 10, and further reducing the negative influence on the subsequent bonding process caused by the introduce of the placeholder unit 12. The placeholder unit 12 can also include one or more of gallium nitride, gallium arsenide, indium Gallium nitride, or aluminum indium gallium phosphide. Further, the material of the placeholder unit 12 can be the same as or different from that of the functional unit 11.

Further, in some exemplary embodiments, when the placeholder unit 12 includes the semiconductor material, the epitaxial wafer structure can further include a second bonding layer 421. The second bonding layer 421 is disposed between the placeholder unit 12 and the carrier substrate 10. The placeholder unit 12 is bonded to the carrier substrate 10 via the second bonding layer 421. By providing the second bonding layer 421, the bonding stability of the placeholder unit 12 and the carrier substrate 10 can be further improved.

Referring to FIG. 3, the second bonding layer 421 can be made of a material including an inorganic material and/or an organic material. The inorganic material can include one or more of oxide, nitride, or metal. The organic material can include a photoresist material.

In some exemplary embodiments, the material of the second bonding layer 421 can include one or more of silicon oxide, silicon nitride, epoxy resin, polyimide, indium tin oxide, or metal. In some exemplary embodiments, the material of the second bonding layer 421 can be an inorganic oxide material or an inorganic nitride material. The material of the second bonding layer 421 can be the same as or different from that of the third bonding layer 110.

In some exemplary embodiments, the second bonding layer 421 can be bonded to the third bonding layer 110 by the method of metal bonding, oxide bonding, or mixed bonding. It should be understood that the specific bonding method depends on the materials of the second bonding layer 421 and the third bonding layer 110.

Referring to FIG. 3, in some exemplary embodiments, the epitaxial wafer structure includes a plurality of function bonding layers 321 spaced from each other. Each of the plurality of function bonding layers 321 is corresponding to one of the plurality of the functional units 11. Further, the first bonding layer 321 is also spaced from the second bonding layer 421.

A method for manufacturing the epitaxial wafer structure is also provided in the present disclosure. FIG. 4 shows a flow chart of the method for manufacturing the epitaxial wafer structure. Referring to FIG. 4, the method includes steps S1.1 to S1.5.

In step S1.1, an epitaxial functional layer 310 is formed on a first native substrate 30.

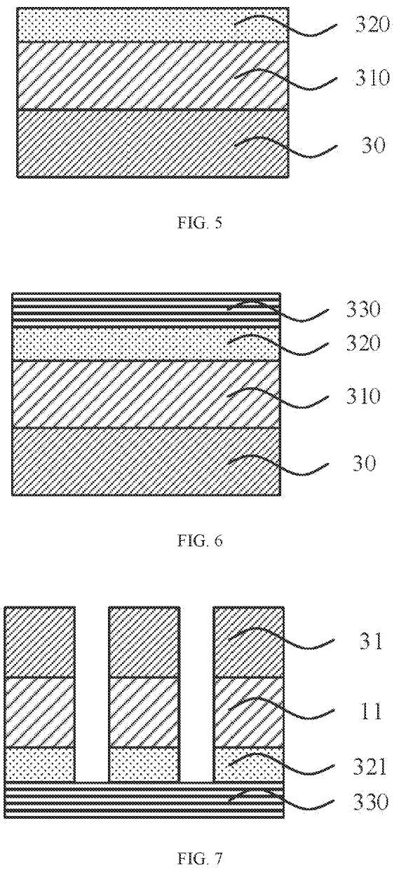

FIG. 5 shows a schematic structural view of forming the epitaxial functional layer 310 on the first native substrate 30. Referring to FIG. 5, the epitaxial functional layer 310 can be epitaxially grown on the first native substrate 30. It should be understood that the first native substrate 30 refers to a substrate for epitaxially growing the epitaxial functional layer 310. In some embodiments, in order to obtain the epitaxial functional layer 310 with a high quality, the first native substrate 30 can be made of a material including one or more of sapphire, silicon carbide, silicon, silicon germanium, gallium nitride, gallium arsenide, aluminum oxynitride, gallium phosphide, or indium phosphide.

In some exemplary embodiments, prior to the step of forming the epitaxial functional layer 310, the method further includes a step of washing the first native substrate 30. For example, the first native substrate 30 can be washed by purified water.

In some exemplary embodiments, the epitaxial functional layer 310 is formed on the first native substrate 30 by chemical vaporous deposition. Further, the epitaxial functional layer 310 is formed on the first native substrate 30 by chemical vapor deposition with an organometallic compound.

In some exemplary embodiments, after the step of forming the epitaxial functional layer 310, the method further includes a step of forming a first bonding material layer 320 on the first native substrate 30. Referring to FIG. 5, the first bonding material layer 320 is formed on a side of the epitaxial functional layer 310 away from the first native substrate 30.

In some exemplary embodiments, the first bonding material layer 320 is formed by physical vapor deposition or chemical vapor deposition.

In some exemplary embodiments, after the step of forming the first bonding material layer 320, the method further includes a step of planarizing a surface of the first bonding material layer 320 away from the epitaxial functional layer 310. In some exemplary embodiments, the planarizing step can be performed by mechanical grinding, wet etching, or chemico-mechanical polishing. The thickness of the first bonding material layer 320 can be reduced in the planarizing step, thereby improving the flatness and the quality of the first bonding material layer 320.

In step S1.2, the epitaxial functional layer 310 and the first native substrate 30 are cut into the plurality of functional units 11 and a plurality of first native sub-substrate 31. The plurality of functional units 11 are respectively disposed on the plurality of first native sub-substrate 31.

In some exemplary embodiments, prior to the step of cutting the epitaxial functional layer 310 and the first native substrate 30, the method further includes a step of providing a first fixing member 330 on a side of the epitaxial functional layer 310 away from the first native substrate 30. FIG. 6 shows a schematic structural view of providing the first fixing member 330 on basis of the structure shown in FIG. 5. Referring to FIG. 6, the first fixing member 330 is provided on the first bonding material layer 320, and is in direct contact with the first bonding material layer 320. Further, the epitaxial functional layer 310 can be fixedly attached to the first fixing member 330. In the subsequent cutting process, the first fixing member 330 will not be cut so that it can play a role in keeping the positions of the functional units 11 obtained by cutting.

The first fixing member 330 can be used to maintain the structural stability of the functional units 11 obtained in the step of cutting. More importantly, by providing the first fixing member 330 on the side of the epitaxial functional layer 310 away from the first native substrate 30, the epitaxial functional layer 310 can be protected during the step of cutting, thereby ensuring the quality of the epitaxial functional layer 310.

In some exemplary embodiments, the first fixing member 330 can be a flexible member such as a blue membrane, a UV cured membrane, or a baf membrane, or a rigid member such as a tray, a ceramic suction cup, or a holder. In some embodiments, the first fixing member 330 can be a flexible member such as a blue membrane. The flexible member has a certain deformable ability, so that the functional units 11 obtained by cutting and attached to the flexible member can be separated from each other easily by stretching the flexible member such as the blue membrane.

FIG. 7 shows a schematic view of a structure obtained by cutting the epitaxial functional layer 310 and the first native substrate 30 on the basis of the structure of FIG. 6. Referring to FIG. 7, the epitaxial functional layer 310 is cut into the plurality of functional units 11. The first native substrate 30 is cut into the plurality of first native sub-substrate 31. Each of the plurality of functional units 11 is disposed on corresponding one of plurality of first native sub-substrate 31. In this way, the transfer of the functional units 11 is facilitated.

In some exemplary embodiments, the step of cutting the epitaxial functional layer 310 and the first native substrate 30 can be performed by laser cutting.

In some exemplary embodiments, in the step of cutting, the epitaxial functional layer 310 and the first native substrate 30 can be cut from a side of the first native substrate 30 away from the epitaxial functional layer 310 towards the epitaxial functional layer 310. Referring to FIG. 7, before the step of cutting, the first native substrate 30 can be inverted, so that the surface of the first native substrate 30 away from the epitaxial functional layer 310 is oriented upward. In this case, the first fixing member 330 can be not cut in the step of cutting to keep the positions of the plurality of functional units 11.

Referring to FIG. 7, in some exemplary embodiments, the first bonding material layer 320 is cut into a plurality of second bonding layers 321 while cutting the epitaxial functional layer 310 and the first native substrate 30. The plurality of second bonding layers 321 are located at a side of the plurality of functional units 11 away from the plurality of first native sub-substrates 31.

In step S1.3, the carrier substrate 10 is provided, and at least some of the plurality of functional units 11 with the first native sub-substrates 31 attached thereto are bonded to the carrier substrate 10, such that each of at least some of the plurality of functional units on the carrier substrate is corresponding in position to one of the plurality of non-defective driver units on the driver substrate.

In some exemplary embodiments, prior to the step of bonding the plurality of functional units 11 to the carrier substrate 10, the method further includes a step of testing the quality of each of the plurality of functional units 11 to determine qualified functional units which can perform the specific function normally and unqualified functional units which are defective functional units. The at least some of the plurality of functional units are selected from the qualified functional units.

In step S1.4, a plurality of placeholder unit(s) 12 are provided on the carrier substrate 10.

In some exemplary embodiments, the unqualified functional unit can be used as the placeholder unit 12. In this case, the step S1.4 includes: bonding at least some of the qualified functional units with the first native sub-substrates 31 attached thereto to the carrier substrate 10, such that each of the at least some of the qualified functional units on the carrier substrate is corresponding in position to one of the plurality of defective driver units on the driver substrate.

In some exemplary embodiments, the step S1.4 of providing the plurality of placeholder units 12 on the carrier substrate 10 includes steps of: a) epitaxially forming a epitaxial placeholder layer 410 containing a semiconductor material on a second native substrate 40; b) forming a second bonding material layer 420 on a side of the epitaxial placeholder layer 410 away from the second native substrate 40; c) cutting the second bonding material layer 420, the epitaxial placeholder layer 410, and the second native substrate 40 respectively into a plurality of second bonding layers 421, a plurality of placeholder units 12, and a plurality of second native sub-substrates 41, wherein the plurality of placeholder units 12 are respectively located on the plurality of second native sub-substrate 41, and the plurality of second bonding layers 421 are respectively located on the plurality of placeholder units 12; and d) bonding at least some of the plurality of placeholder units 12 with the second native sub-substrates 41 attached thereto to the carrier substrate 10 via the second bonding layers 421 attached thereto, such that each of the at least some of the plurality of placeholder units 12 on the carrier substrate is corresponding in position to one of the plurality of defective driver units on the driver substrate 20.

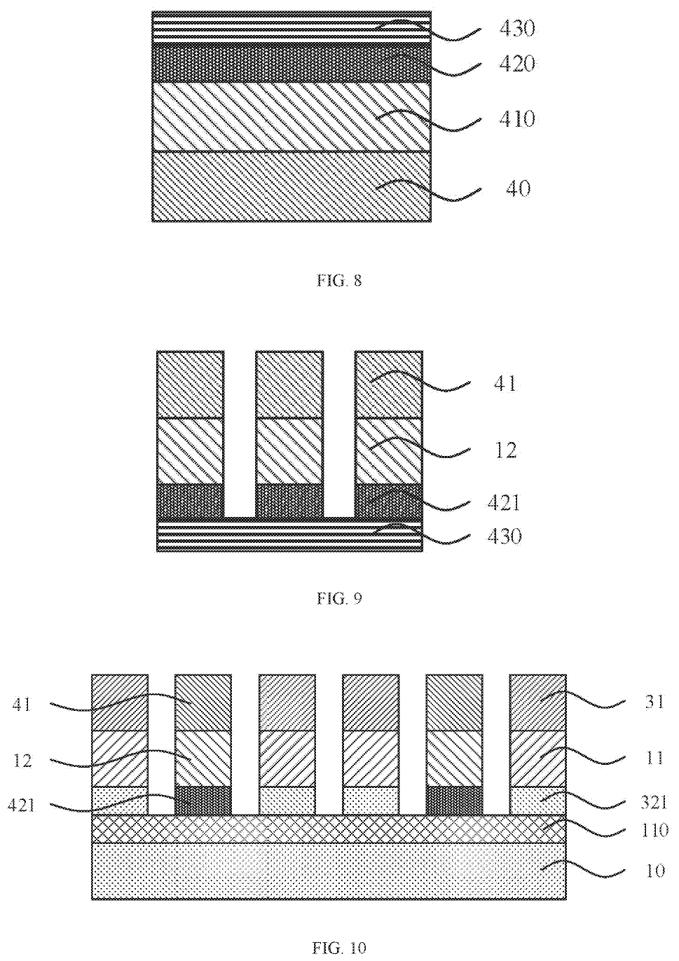

FIG. 8 shows a schematic structural view of forming the epitaxial placeholder layer 410 and the second bonding material layer 420 on the second native substrate 40. Referring to FIG. 8, the epitaxial placeholder layer 410 is formed on the second native substrate 40, and the second bonding material layer 420 is formed on the side of the epitaxial placeholder layer 410 away from the second native substrate 40.

In some exemplary embodiments, the epitaxial placeholder layer 410 can be a layer of a material epitaxially grown on the second native substrate 40. The step of forming the epitaxial placeholder layer 410 on the second native substrate 40 can be performed by chemical vapor deposition, such as chemical vapor deposition with a metallo-organic compound.

In some exemplary embodiments, the second bonding material layer 420 can be formed by physical vapor deposition or chemical vapor deposition.

In some exemplary embodiments, after forming the second bonding material layer 420, the method further includes a step of planarizing a surface of the second bonding material layer 420 away from the epitaxial placeholder layer 410. In some exemplary embodiments, the step of planarizing can be performed by mechanical grinding, wet etching, or chemico-mechanical polishing. The thickness of the second bonding material layer 420 can be reduced in the step of planarizing, thereby improving the flatness and the quality of the second bonding material layer 420.

Further, after the step of planarizing, the sum of the thicknesses of the second bonding material layer 420 and the epitaxial placeholder layer 410 is equal to the sum of the thicknesses of the first bonding material layer 320 and epitaxial functional layer 310.

Referring to FIG. 8, in some exemplary embodiments, the method further includes a step of providing a second fixing member 430 on a side of the second bonding material layer 420 away from the second native substrate 40. As shown in FIG. 8, the second fixing member 430 is provided on the second bonding material layer 420 and in direct contact with the second bonding material layer 420. Further, the epitaxial placeholder layer 410 can be fixedly attached to the second fixing member 430. The second fixing member 430 is configured to keep the positions of the plurality of placeholder units 12 obtained by cutting.

In some exemplary embodiments, the second fixing member 430 can be a flexible member such as a blue membrane, a UV cured membrane, a baf film, or a rigid member such as a tray, a ceramic suction cup, or a holder. In some exemplary embodiments, the second fixing member 430 can be a flexible member such as a blue membrane.

FIG. 9 shows a schematic structural view of a structure obtained by cutting the structure of FIG. 8. Referring to FIG. 9, before the step of cutting, the second native substrate 40 can be inverted, so that the surface of the second native substrate 40 away from the epitaxial functional layer 310 is oriented upward. In the step of cutting, the second fixing member 430 is not cut so that it can play a role in keeping the positions of the placeholder units 12 obtained.

Referring to FIG. 9, in the step of cutting, the second bonding material layer 420 is cut into the plurality of second bonding layers 421. The epitaxial placeholder layer 410 is cut into the plurality of placeholder units 12. The second native substrate 40 is cut into the plurality of second native sub-substrates 41. The plurality of placeholder units 12 and the plurality of second bonding layers 421 are respectively located on the plurality of second native sub-substrates 41.

In some exemplary embodiments, the step of cutting can be performed by laser cutting.

It should be understood that the placeholder unit 12 and the functional unit 11 can be made by similar methods and thus have similar structures, so that they can be transferred to the same carrier substrate 10 in the same process, thereby simplifying the manufacture process.

FIG. 10 shows a schematic structural view of a structure obtained by transferring the placeholder units 12 and the functional units 11 onto the carrier substrate 10. Referring to FIG. 10, the functional units 11 formed in FIG. 7 and the placeholder units 12 formed in the FIG. 9 can be transferred to the carrier substrate 10 in a preset manner. It should be understood that the arrangement of the functional units 11 and the placeholder units 12 on the carrier substrate 10 depends on the arrangement of the non-defective driver units 21 and the defective driver units 22 on the driver substrate 20 to be bonded to the carrier substrate 10.

Referring to FIG. 10, in some exemplary embodiments, the functional units 11 are spaced from each other. The placeholder units 12 are spaced from each other. The functional unit 11 is spaced from the placeholder unit 12. The first native sub-substrates 30 are positioned on a side of the functional units 11 away from the carrier substrate 10. The second native sub-substrates 41 are positioned on a side of the placeholder units 12 away from the carrier substrate 10.

Referring to FIG. 10, in some exemplary embodiments, a third bonding layer 110 can be formed on the carrier substrate 10. The third bonding layer 110 can cover the carrier substrate 10. The third bonding layer 110 can be formed by chemical vapor deposition. Alternatively, the third bonding layer 110 can be formed by oxidizing the carrier substrate 10.

In some exemplary embodiments, prior to the step of transferring the functional units 11 and the placeholder units 12 onto the carrier substrate 10, the method further includes a step of plasma-processing at least one of the third bonding layer 110, the plurality of first bonding layers 321, or the plurality of second bonding layers 421.

Referring to FIG. 10, in some exemplary embodiments, the functional units 11 can be bonded to the third bonding layer 110 via the first bonding layers 321, so as to be bonded to the carrier substrate 10. The placeholder units 12 can be bonded the third bonding layer 110 via the second bonding layers 421, so as to be bonded to the carrier substrate 10.

In some exemplary embodiments, after the step of transferring the functional units 11 and the placeholder units 12 onto the carrier substrate 10, the method further includes a step of heating the carrier substrate 10 to enhance the bonding strength between the functional units 11 and the carrier substrate 10 and between the placeholder units 12 and the carrier substrate 10.

In some exemplary embodiments, the area of the carrier substrate 10 can be larger than that of the first native substrate 30. It should be understood that when the area of the carrier substrate 10 is larger, the number of the functional units 11 formed by using one first native substrate 30 may not be sufficient to fill one carrier substrate 10. Therefore, in the practical production, the functional units 11 formed by using more than one first native substrate 30 may be transferred onto one carrier substrate 10 to fill the carrier substrate 10.

In step S1.5, the first native sub-substrates 31 are removed from the functional units 11, so that the functional units 11 are exposed.

FIG. 11 shows a schematic view of a structure obtained by removing the first native sub-substrate 31 from the structure of FIG. 10. As shown in FIG. 10 and FIG. 11, the functional units 11 are exposed after removing the first native substrates 31.

In some exemplary embodiments, the second native sub-substrates 41 are also removed while removing the first native sub-substrate 31, so that the placeholder units 12 are exposed.

In some exemplary embodiments, the step of removing the first native sub-substrates 31 or the second native sub-substrates 41 can be performed by mechanical grinding, wet etching, or chemico-mechanical polishing.

In some exemplary embodiments, after the functional units 11 are exposed, the method further includes a step of forming a dielectric layer 120 between any two adjacent functional units 11. By forming the dielectric layer 120, the positions of the functional units 11 can be kept to prevent displacement thereof and thus ensure the accuracy of the positions.

In some exemplary embodiments, the dielectric layer 120 can be in contact with the carrier substrate 10 or the third bonding layer 110 to further improve the stability of the functional units 11.

In some exemplary embodiments, the material of the dielectric layer 120 can include a dielectric material such as an insulating material. For example, the material of the dielectric layer 120 can include a photoresist material, and the step of forming the dielectric layer 120 includes spin-coating the photoresist material onto the carrier substrate 10 and exposing the photoresist material to solidify the photoresist material.

It should be understood that the epitaxial wafer structure as shown in FIG. 3 can be obtained by steps S1.1 to 1.5.

It should be understood that in the above embodiments of the manufacturing method, the placeholder unit 12 contains the semiconductor material, and the placeholder unit 12 has a similar structure to the functional unit 11. On another aspect, the present disclosure also provides another manufacturing method, which is substantially the same as the above manufacturing method, except the step of providing the placeholder unit 12 on the carrier substrate 10. In this method, the step S1.4 of providing the plurality of placeholder units 12 on the carrier substrate 10 includes steps of: forming the plurality of placeholder units 12 with the dielectric material of the dielectric layer while forming the dielectric layer 120. That is, the step S1.4 and the step of forming the dielectric layer 120 can be performed simultaneously.

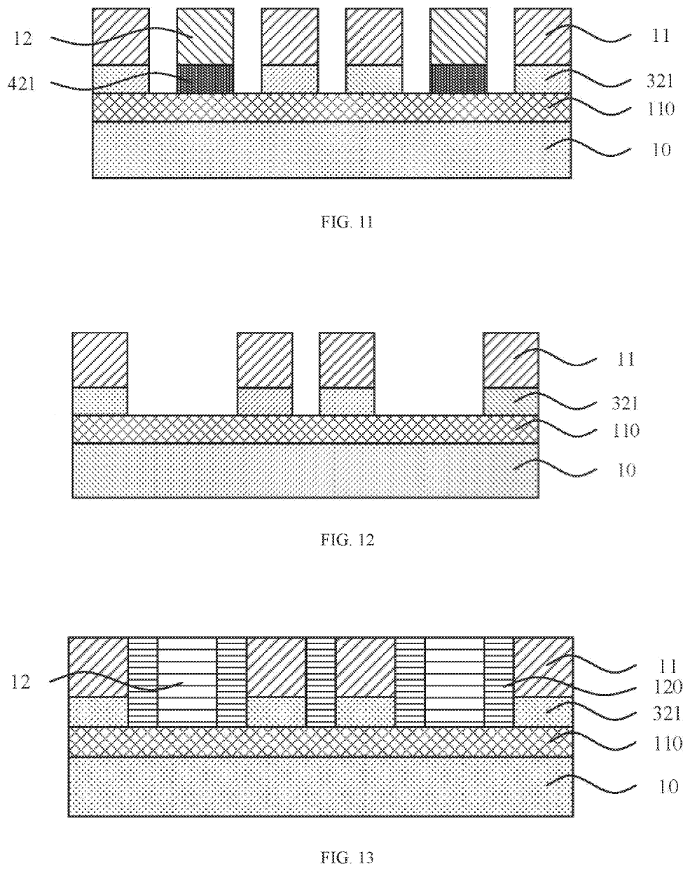

FIG. 12 shows a schematic view of a structure obtained by transferring the functional units 11 onto the carrier substrate 10 with the placeholder units 12 and the dielectric layer 120 having not been provided. FIG. 13 show a schematic view of forming the placeholder units 12 and the dielectric layer 120 on basis of the structure of FIG. 12.

Referring to FIGS. 12 and 13, in some exemplary embodiments, the step S1.4 of providing the plurality of placeholder units 12 on the carrier substrate 10 is performed after the steps S1.3 and S1.5. In step S1.4, the plurality of placeholder units 12 and the dielectric layer 120 are simultaneously formed with the dielectric material, thereby forming the epitaxial wafer structure as shown in FIG. 3.

In the epitaxial wafer structure of the present disclosure, the carrier substrate 10, the functional unit 11, and the placeholder unit 12 are included. The position of the functional unit 11 on the carrier substrate 10 corresponds to the position of the non-defective driver unit 21 on the driver substrate 20, and the position of the placeholder unit 12 on the carrier substrate 10 corresponds to the position of the driver unit 22 on the driver substrate 20. By providing the placeholder unit 12, the epitaxial wafer structure can be normally bonded to the driver substrate 20 to allow the electrical connection between the non-defective driver unit 21 and the functional unit 11, thereby avoiding the mispairing problem which is unavoidable in the conventional technology. In addition, the functional unit 11 and the effective drive circuit can be saved, and the yield of the resulting devices can also be improved.

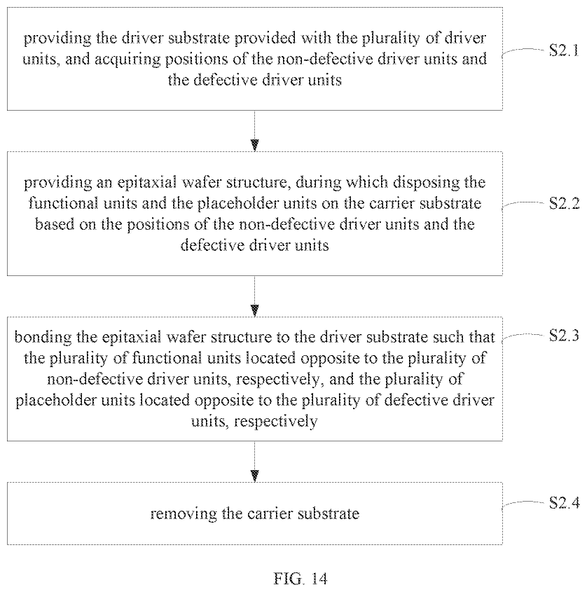

Further, a method for manufacturing a functional device on basis of the above epitaxial wafer structure is further provided in the present disclosure. FIG. 14 shows a flow chart of the method. Referring to FIG. 14, the method includes the following steps of S2.1 to 2.4.

In step S2.1, a driver substrate 20 disposed with a plurality of driver units is provided, and positions of non-defective driver units 21 and defective driver units 22 are acquired.

The driver substrate 20 disposed with the plurality of driver units is shown in FIG. 2. FIG. 15 shows a schematic structural cross-sectional view taken along B-B′ of FIG. 2. It should be understood that line B-B′ of FIG. 2 is corresponding to the line A-A′ of FIG. 1. Referring to FIG. 15, the driver units disposed on the driver substrate 20 includes non-defective driver units 21 and defective driver units 22.

In some exemplary embodiments, the size of the driver substrate 20 is the same as that of the carrier substrate 10.

In some exemplary embodiments, the driver substrate 20 can be a wafer, and the driver unit can be an integrated circuit formed on the wafer. The material of the driver substrate 20 can include semiconductor material. For example, the material of the driver substrate 20 can be one or more of silicon, silicon germanium, gallium nitride, or silicon carbide.

Referring to FIG. 15, in some exemplary embodiments, a plurality of fourth bonding layers 210 can be disposed on the driver substrate 20. The plurality of fourth bonding layers 210 can be disposed on the plurality of driver units 20 at a side of the plurality of driver units 20 away from the driver substrate 20. The fourth bonding layer 210 can be made of a conductive material. The fourth bonding layer 210 can be electrically connected to the driver unit.

The step of acquiring the positions of the non-defective driver units 21 and the defective driver units 22 can include: testing the electrical property and/or the optical property of each of the driver units; determine whether each of the driver units is a non-defective driver unit 21 or a defective driver unit 22 on the basis of the testing results, and recording the position of each of the driver units on the driver substrate 20.

In step S2.2, the epitaxial wafer structure is provided, during which disposing the functional units 11 and the placeholder units 12 on the carrier substrate 10 based on the positions of the non-defective driver units 21 and the defective driver units 22.

The epitaxial wafer structure in step S2.2 can be the epitaxial wafer structure as shown in FIG. 1 or 3. Further, the epitaxial wafer structure can be manufactured by steps S1.1 to S1.5, during which the functional units 11 and the placeholder units 12 are positioned on the carrier substrate 10 correspondingly to the positions of the non-defective driver units 21 and the defective driver units 22 acquired in step S2.1.

As shown in FIGS. 1 and 2, the positions of the functional units 11 on the carrier substrate 10 are corresponding to the positions of the non-defective driver units 21 on the driver substrate 20, and the positions of the placeholder units 12 on the carrier substrate 10 are corresponding to the positions of the defective driver units 22 on the driver substrate 20.

In step S2.3, the epitaxial wafer structure is bonded to the driver substrate 20 such that the plurality of functional units 11 are positioned opposite to the plurality of non-defective driver units 21, respectively, and the plurality of placeholder units 12 are positioned opposite to the plurality of defective driver units 22, respectively.

In some exemplary embodiments, prior to the step of bonding the epitaxial wafer structure to the driver substrate 20, the method further includes: forming an electrode layer 130 on the plurality of functional units 11 and forming a fifth bonding layer 220 on the plurality of functional units 11.

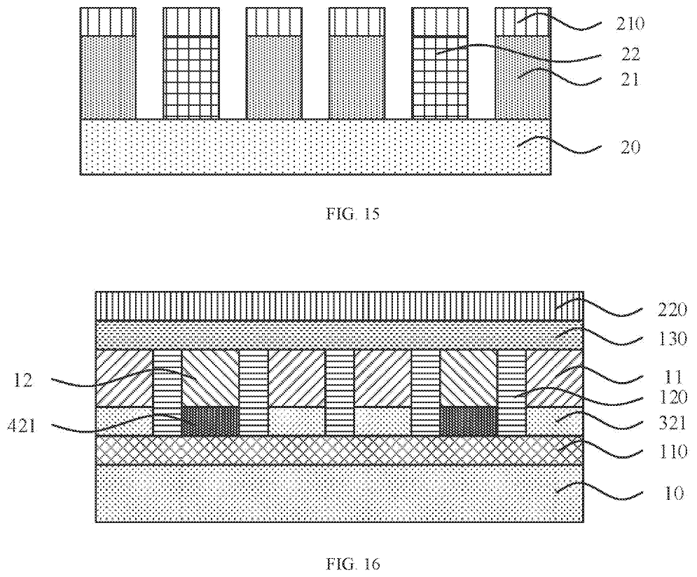

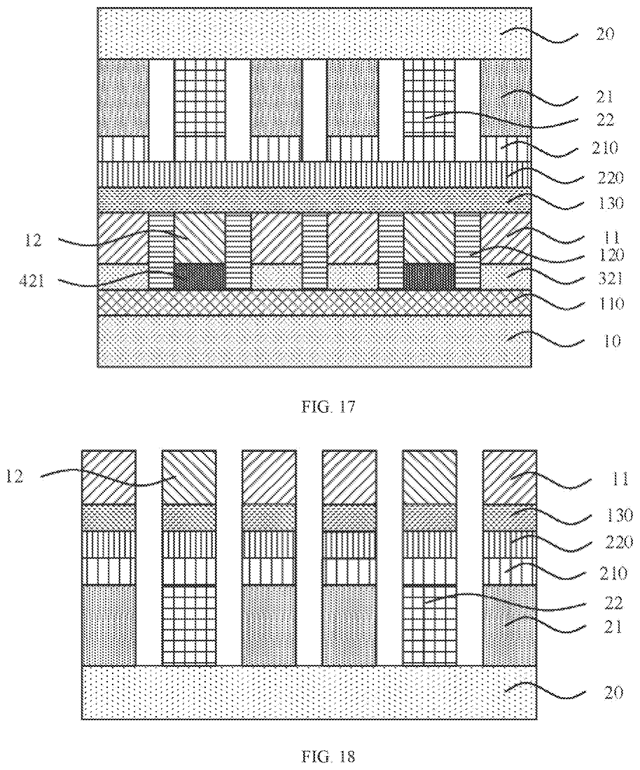

FIG. 16 shows a schematic structural view of forming the electrode layer 130 and the fifth bonding layer 220 on the basis of the structure of FIG. 3. Referring to FIG. 16, the electrode layer 130 and the fifth bonding layer 220 are successively formed on the functional units 11 and the dielectric layer 120. The fifth bonding layer 220 is stacked on the electrode layer 130.

In some exemplary embodiments, the electrode layer 130 can be made of a conductive material. For example, the material of the electrode layer 130 can include conductive metal oxide. The electrode layer 130 can be in direct contact with the functional units 11.

In some exemplary embodiments, the electrode layer 130 can be patterned. That is, the electrode layer 130 can be etched to form a circuit structure with a specific pattern, so that the functional units 11 can be electrically connected to the non-defective driver units 21 in a certain mode.

In some exemplary embodiments, the fifth bonding layer 220 is made of a conductive material. The fifth bonding layer 220 can be electrically connected to the functional units 11. In some exemplary embodiments, the material of the fifth bonding layer 220 can include metal.

FIG. 17 shows a schematic view of a structure obtained by bonding the epitaxial wafer structure of FIG. 16 to the driver substrate of FIG. 15. Referring to FIG. 17, the driver substrate 20 can be inverted, so that the fourth bonding layers 210 can be in contact with and bonded to the fifth bonding layer 220, thereby bonding the functional units 11 to the non-defective driver units 21 and bonding the placeholder units 12 to the defective driver units 22. Due to the position correspondence between the functional units 11 and the non-defective driver units 21 and between the placeholder units 12 and the defective driver units 22, when the epitaxial wafer structure is bonded to the driver substrate 20, the functional units 11 can be positioned opposite to the non-defective driver units 21, and the placeholder units 12 can be positioned opposite to the defective driver units 22.

In step S2.4, the carrier substrate 10 is removed.

FIG. 18 shows a schematic structural view of removing the carrier substrate 10 from the structure of FIG. 17. Referring to FIG. 18, the carrier substrate 10 is removed. The third bonding layer 110, the second bonding layer 421, and the first bonding layer 321 can also be removed, so as to expose the surfaces of the functional units 11 away from the driver substrate 20.

Referring to FIG. 18, prior to the step of removing the carrier substrate 10, the carrier substrate 10 can be inverted, so that the carrier substrate 10 is positioned above the driver substrate 20.

In some exemplary embodiments, the step of removing the carrier substrate 10, the third bonding layer 110, the second bonding layer 421, or the first bonding layer 321 can be performed by mechanical grinding, wet etching, or chemico-mechanical polishing.

Referring to FIG. 18, in some exemplary embodiments, after the step of removing the carrier substrate 10, the third bonding layer 110, the second bonding layer 421, or the first bonding layer 321, the method further includes a step of etching and removing the dielectric layer 120, along with portions of the electrode layer 130 and the fifth bonding layer 220 overlapping with the dielectric layer 120. Further, a mask allowing the dielectric layer 120 exposed can be provided above the driver substrate 20, and then the dielectric layer 120 and portions of the electrode layer 130 and the fifth bonding layer 220 overlapping with the dielectric layer 120 are etched and removed.

It should be understood that the functional device can be manufactured by the steps S2.1 to 2.4. The functional device can be a display chip.

A functional device is further provided in the present disclosure. Referring to FIG. 18, the functional device includes a driver substrate 20, a plurality of driver units, a plurality of functional units 11, and a plurality of placeholder units 12.

The plurality of the driver units are disposed on the driver substrate 20 and include a plurality of non-defective driver units 21 and a plurality of defective driver units 22. The functional units 11 are positioned opposite to and electrically connected to the non-defective driver units 21. The placeholder units 12 are positioned opposite to the defective driver units 22.

In some exemplary embodiments, the functional device further includes a plurality of sixth bonding layers disposed between the plurality of non-defective driver units 21 and the plurality of functional units 11 and between the plurality of defective driver units 22 and the plurality of placeholder units 12. The sixth bonding layer can include a fourth bonding layer 220 and a fifth bonding layer 230 stacked with each other.

In some exemplary embodiments, the sixth bonding layer is made of metal.

In some exemplary embodiments, the functional device further includes a plurality of electrode layers 130 disposed between the plurality of non-defective driver units 21 and the plurality of functional units 11 and between the plurality of defective driver units 22 and the plurality of placeholder units 12.

It should be understood that in some exemplary embodiments, the functional device can include a micro light emitting diode chip. Accordingly, the functional unit can include a micro light emitting diode.

It should be noted that the above embodiments are for illustrative purposes only and are not intended to limit the present disclosure.

It should be understood that unless explicitly indicated herein, the order of the steps to be performed is not strictly limited, and the steps can be performed in some other order. Moreover, at least some of the steps in the preparation process may include multiple sub-steps or stages, which are not necessarily to be performed at the same time, but can be performed at different time. The order to perform the sub-steps or stages is not necessarily successive. Instead, the sub-steps or stages can be performed alternately or interchangeably with at least some of other steps or sub-steps or stages of other steps.

Each embodiment in the descriptions is described in a progressive manner, and each embodiment focuses on its differences from other embodiments. The same and similar parts of each embodiment can be referred to each other.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

What is claimed is:

1. An epitaxial wafer structure, configured to be bonded to a driver substrate provided with a plurality of driver units comprising a plurality of non-defective driver units and a plurality of defective driver units, comprising:
a carrier substrate;
a plurality of functional units disposed on the carrier substrate; and
a plurality of placeholder units disposed on the carrier substrate;
wherein each of the plurality of functional units on the carrier substrate is corresponding in position to one of the plurality of non-defective driver units on the driver substrate; and
each of the plurality of placeholder units on the carrier substrate is corresponding in position to one of the plurality of defective driver units on the driver substrate.

2. The epitaxial wafer structure of claim 1, wherein each of the plurality of functional units comprises a micro light emitting diode.

3. The epitaxial wafer structure of claim 1, wherein surfaces of the placeholder units away from the carrier substrate are flush with surfaces of the functional units away from the carrier substrate.

4. The epitaxial wafer structure of claim 1, further comprising a plurality of first bonding layers disposed between the plurality of functional units and the carrier substrate, respectively, wherein the plurality of functional units are bonded to the carrier substrate via the plurality of first bonding layers.

5. The epitaxial wafer structure of claim 4, further comprising a third bonding layer covering the carrier substrate and disposed between the plurality of first bonding layers and the carrier substrate, wherein the plurality of function bonding layers are bonded to the third bonding layer.

6. The epitaxial wafer structure of claim 5, wherein a material of the plurality of first bonding layers is selected from a group consisting of silicon oxide, silicon nitride, epoxy resin, polyimide, indium tin oxide, metal, and any combination thereof; and/or
a material of the third bonding layer is selected from a group consisting of silicon oxide, silicon nitride, epoxy resin, polyimide, indium tin oxide, metal, and any combination thereof.

7. The epitaxial wafer structure of claim 1, wherein the plurality of placeholder units are made of a semiconductor material, the epitaxial wafer structure further comprises a plurality of second bonding layers disposed between the plurality of placeholder units and the carrier substrate, respectively, and the plurality of placeholder units are bonded to the carrier substrate via the plurality of second bonding layers.

8. The epitaxial wafer structure of claim 1, further comprising a dielectric layer disposed in a space between any adjacent two of the plurality of functional units, between any adjacent two of the plurality of placeholder units, or between one of the plurality of functional units and one of the plurality of placeholder units adjacent to each other.

9. The epitaxial wafer structure of claim 8, wherein the plurality of placeholder units are made of a dielectric material same as that of the dielectric layer.

10. A method for manufacturing the epitaxial wafer structure of claim 1, comprising:
forming an epitaxial functional layer on a first native substrate;
cutting the epitaxial functional layer and the first native substrate into a plurality of functional units and a plurality of first native sub-substrates, wherein the plurality of functional units are respectively located on the plurality of first native sub-substrates;
providing the carrier substrate, and bonding the plurality of functional units with the plurality of first native sub-substrates attached thereto to the carrier substrate so that the plurality of functional units are positioned between the plurality of first native sub-substrates and the carrier substrate;
disposing a plurality of placeholder units on the carrier substrate; and
removing the plurality of first native sub-substrates to expose the plurality of functional units.

11. The method of claim 10, further comprising: prior to the cutting the epitaxial functional layer and the first native substrate, forming a first bonding material layer on a side of the epitaxial functional layer away from the first native substrate; and
cutting the first bonding material layer into a plurality of first bonding layers while cutting the epitaxial functional layer and the first native substrate, wherein the plurality of first bonding layers are respectively located on the plurality of functional units at a side away from the plurality of first native sub-substrates.

12. The method of claim 10, wherein the disposing the plurality of placeholder units on the carrier substrate comprises:
epitaxially forming an epitaxial placeholder layer with a semiconductor material on a second native substrate;
forming a second bonding material layer on a side of the epitaxial placeholder layer away from the second native substrate;
cutting the second bonding material layer, the epitaxial placeholder layer, and the second native substrate into a plurality of second bonding layers, a plurality of placeholder units, and a plurality of second native sub-substrates, respectively, wherein the plurality of placeholder units are respectively located on the plurality of second native sub-substrates, and the plurality of second bonding layers are respectively located on the plurality of placeholder units; and
bonding the plurality of placeholder units with the plurality of second native sub-substrates attached thereto to the carrier substrate via the plurality of second bonding layers so that the plurality of placeholder units are positioned between the plurality of second native sub-substrates and the carrier substrate.

13. The method of claim 10, further comprising: forming a dielectric layer between any two adjacent of the plurality of functional units by using a dielectric material;
wherein the disposing the plurality of placeholder units on the carrier substrate comprises: forming the plurality of placeholder units with the dielectric material while forming the dielectric layer.

14. A functional device, comprising:
a driver substrate;
a plurality of driver units disposed on the driver substrate and comprising a plurality of non-defective driver units and at least one defective driver units;
a plurality of functional units located opposite to and electrically connected to the plurality of non-defective driver units, respectively; and
a plurality of placeholder units located opposite to the plurality of defective driver units, respectively.

15. The functional device of claim 14, further comprising:
a plurality of sixth bonding layers disposed between the plurality of functional units and the plurality of non-defective driver units, respectively;
wherein the plurality of functional units are bonded to the plurality of non-defective driver units via the plurality of sixth bonding layers, respectively.

16. The functional device of claim 15, wherein a material of the plurality of sixth bonding layers comprises metal.

17. The functional device of claim 14, further comprising:
a plurality of electrode layers disposed between the plurality of functional units and the plurality of non-defective driver units, respectively.

18. A method for manufacturing the functional device of claim 14, comprising:
providing the driver substrate provided with the plurality of driver units, and acquiring positions of the plurality of non-defective driver units and the plurality of defective driver units;
providing an epitaxial wafer structure comprising a carrier substrate and the plurality of functional units and the plurality of placeholder units disposed on the carrier substrate, wherein each of the plurality of functional units on the carrier substrate is corresponding in position to one of the plurality of non-defective driver units on the driver substrate; and each of the plurality of placeholder units on the carrier substrate is corresponding in position to one of the plurality of defective driver units on the driver substrate;
bonding the epitaxial wafer structure to the driver substrate such that the plurality of functional units located opposite to the plurality of non-defective driver units, respectively, and the plurality of placeholder units located opposite to the plurality of defective driver units, respectively; and
removing the carrier substrate.

19. The method of claim 18, wherein the driver substrate is further provided with a fourth bonding layer located on the plurality of driver units;
the providing the epitaxial wafer structure comprises: forming a fifth bonding layer on the plurality of the functional units; and
the bonding the epitaxial wafer structure to the driver substrate comprises: bonding the fourth bonding layer to the fifth bonding layer to bond the plurality of driver units to the plurality of the functional units.

20. The method of claim 18, further comprising: prior to the bonding the epitaxial wafer structure to the driver substrate, forming an electrode layer on the plurality of the functional units.
